(19) United States
(12) Patent Application Publication
(10) Pub. No.: US 2008/0198321 A1
(43) Pub. Date: Aug. 21, 2008

(54) Liquid crystal optical device and method for producing the same

(76) Inventors: Kohki Hiroshima, Kofu-shi (JP); Nobuyoshi Nakagawa, Tokorozawa-shi (JP)

Correspondence Address: WENDEROTH, LIND & PONACK, L.L.P., 2033 K STREET N. W., SUITE 800, WASHINGTON, DC, 20006-1021, US

(21) Appl. No.: 12/071,249

(22) Filed: Feb. 19, 2008

(30) Foreign Application Priority Data
Feb. 20, 2007 (JP) 2007-040079

(51) Int. Cl. G02F 1/1333; H01L 21/02

(52) U.S. Cl. 349/158; 438/30

(57) ABSTRACT

A liquid crystal optical device comprising a porous structure having numerous through holes or blind holes between substrates with driving electrodes and liquid crystal filled in between the substrate makes it possible to readily and stably control orientation of liquid crystal molecules by applying an electric-voltage between the electrodes and ensure a sufficient optical length of the liquid crystal, thus to significantly improve the response speed of the liquid crystal. The porous structure may be formed by, for instance, subjecting a high-purity aluminum material to anodizing treatment or subjecting a material of glass, resin, silicon, carbon or ceramic to etching treatment

### BACKGROUND OF THE INVENTION

1. Field of the Invention

This invention relates to a liquid crystal optical device, and more particularly, to a liquid crystal optical device or an optical disk device having an autofocusing function and a micro-macro switching function in a subminiature camera built into a cell phone, personal digital assistance (PDA), digital equipment and so on, or a liquid crystal optical device such as a liquid crystal aberration compensation device for compensating aberration produced in recording and playing with an optical pickup in an optical disk device. To be more specific, the present invention relates to a liquid crystal device in which a liquid crystal material and a porous structure are sandwiched and a method for producing the same.

2. Description of the Related Art

Conventionally, there have been known various types of liquid crystal devices in which a liquid crystal is sandwiched between substrates having electrodes. For instance, in optical disk devices such as CD and DVD used as data recording media, aberration (distortion of a converging spot), which is caused by deviation in thickness or warpage of a rotating optical disk, should be corrected to assure recording and playing accuracy. Thus, a liquid crystal aberration compensation device, which has a liquid crystal sandwiched between substrates having electrodes formed in concentric rings, is used to perform different phase controls at the central part and peripheral part of a light beam (e.g. Patent Literature 1).

In a conventional liquid crystal device, a molecular array state of a liquid crystal material is electrically controlled to change the properties such as a light refractive index. By two-dimensionally or three-dimensionally controlling a change in distribution of the refractive index, phase delay in each light path and the aspect of the refractive index in the light path can be controlled, so that the liquid crystal device should efficiently be useful for an electronically varifocal lens and a liquid crystal aberration compensation device. However, it is necessary to provide adequate provision of liquid crystal along the light path between oriented films opposite to liquid crystal optical cells in order to maximize the practicable effect of refraction of light. Thus, the liquid crystal is required to have a layer thickness d (between the oriented films) on the order of 30 to 100 μm, which is extremely thicker than that of a common liquid crystal display device having a thickness on the order of several microns at the utmost.

It has been known that the liquid crystal has a response speed inversely proportional to the square of the layer thickness d (between the oriented films) of the liquid crystal. In the case of the liquid crystal optical cell having such a large thickness, the response speed thereof is on the order of several hundred milliseconds. That is, the conventional liquid crystal optical devices mostly have a problem of low response speed. As illustrated in FIG. 1, the liquid crystal having the layer thickness d (between the oriented films) comprises interface layers K0 and K1 close to the oriented film of the substrate and a bulk layer P existing in the central region.

The change of the molecular array state of the liquid crystal, which is caused in the interface layers K0 and K1 by applying an electric field, is smaller Man that in the bulk layer P, and the rate of change of the molecular array state of the liquid crystal is also slow due to the applied electric field. By removing the applied electric field, the molecular array state of the liquid crystal returns to its initial state before applying the electric field, but the change of the molecular array state is due to native orientational relaxation into the array state determined by an oriented layer in the interface. Hence, the speed at which the array state returns to the initial molecular array state of the liquid crystal material is fast in the interface layers K0 and K1 near the oriented film, but the response time to recover the state in the bulk layer P far from the oriented film is lengthened enormously.

Thus, the conventional device of this kind entailed disadvantages such that the slow response speed in controlling the liquid crystal optical device results in largely restricting a variable focusing function and an aberration compensating function in an optical device using the liquid crystal optical device and interferes practical application of the liquid crystal optical device.

To overcome the disadvantages as described above, there has been proposed an optical device having two liquid crystal layers (e.g. Patent Literature 2). Further, there has been proposed a liquid crystal structure capable of redeeming the aforementioned disadvantages, in which the liquid crystal is microencapsulated to form an aggregate of liquid crystal (e.g. Patent Literature 3). Moreover, there has been proposed an orientational control function formed in a steric structure having polymer network formed in a liquid crystal layer (e.g. Non-Patent Literature 1).

Patent Literature 1: Japanese Unexamined Patent Publication No. 2002-237077(A)

Patent Literature 2: Japanese Unexamined Patent Publication No. 2006-91826(A)

Patent Literature 3: Japanese Unexamined Patent Publication No. 2001-75082(A)

Non-Patent Literature 1: “Liquid crystal molecular orientation control by stretched fine polymer structure”, Liquid crystal, 2006, vol. 10, No. 1, pp. 60-66

However, the aforementioned liquid crystal optical cell (liquid crystal optical device) has modest effects of resolving the problems as described above and improving the response speed, but it has still another problem suffering inconvenience in stability of characteristics of the device from difficulty in forming uniform structural alignment (difficulties in reproducing the structure), thus to disadvantageously hampering practical application. Also, the approach proposed in Patent Literature 2 has a disadvantage of difficulty in forming the two liquid crystal layers.

Meanwhile, in order to gain the change in refractive index required for applying the liquid crystal optical device to practical use, it is necessary to ensure a sufficient optical length L of the liquid crystal so as to pass a light beam through the large thickness of the liquid crystal layer. However, it has been known that the response times τᵣ and τ_{d} are lengthened in proportion to the square of the layer thickness d (between the oriented films) of the liquid crystal.

Consequently, an object of the present invention is to provide a liquid crystal optical device capable of ensuring the sufficient optical length L of the liquid crystal and significantly improving the response speed by placing a porous structure having numerous through holes or blind holes between substrates constituting a liquid crystal optical cell.

### SUMMARY OF THE INVENTION

To attain the object described above according to the present invention, there is provided a liquid crystal optical device comprising a plurality of substrates having electrodes, a porous structure having numerous through holes or blind holes and disposed between the aforementioned substrates, and liquid crystal held between the aforesaid substrates to be filled in the aforesaid through holes or blind holes.

As one example, the through holes or blind holes each are formed in a cylindrical or hexagonal column structure. The aperture ratio s of the porous structure is 50% to 80%. The pitch between the holes in the porous structure is 50 to 5000 nm.

As one example, the liquid crystal has in-plane orientation having no anisotropy and being independent on polarization direction by subjecting the inner wall surface of the porous structure to orienting treatment and subjecting the surface of the aforementioned substrate, on which the porous structure is formed, to orienting treatment.

As one example, the upper surface or lower surface of the porous structure is subjected to blacking treatment to reduce light leakage. This blacking treatment is effected to shield a part other than a light path. To be more specific, an area other than an optically effective area is subjected to the blacking treatment, thus to improve contrast

In the liquid crystal device of the invention, the porous structure is disposed between the substrates to bring the major part of the liquid crystal close to an oriented layer, consequently to form interface layers and conversely reduce a bulk layer. The in-plane orientation of the liquid crystal has no macroscopic anisotropy, and therefore, it has isotropy, and various optical characteristics are independent on polarization direction.

To attain the object described above according to the present invention, there is provided a method for producing a liquid crystal optical device with a plurality of substrates having electrodes and liquid crystal held between the aforesaid substrates, which comprises the processes of forming the electrodes on the substrates, formimg a porous structure having an inner wall surface and numerous through holes or blind holes, subjecting the inner wall surface of the porous structure to orienting treatment, disposing the porous structure on one of the substrates with the electrodes, assembling the other substrate with the substrate on which the porous structure is disposed, and introducing the liquid crystal into between the assembled substrates.

As one example, in the process of forming the porous structure, an alumina porous structure may be formed by subjecting a high-purity aluminum material to anodizing treatment Further in the process of forming the porous structure, the porous structure may formed by subjecting a material of glass, resin, silicon, carbon or ceramic to etching treatment.

As one example, in the process of producing the aforementioned liquid crystal optical device, the surface onto which the porous structure of the substrate is attached may further be subjected to the orienting treatment

To attain the object described above according to the present invention, there is provided a method for producing a liquid crystal optical device with a plurality of substrates having electrodes and liquid crystal held between the aforesaid substrates, which comprises the processes of forming the electrodes on the substrates, disposing a high-purity aluminum material on one or more substrates having electrodes or forming a high-purity aluminum film on the aforesaid one or more substrates, subjecting the aforesaid high-purity aluminum material or high-purity aluminum film to anodizing treatment to form a porous structure having an inner wall surface and numerous through holes or blind holes, subjecting the inner wall surface of the porous structure to orienting treatment, assembling the other substrate with the substrate on which the porous structure is disposed, and introducing the liquid crystal into between the assembled substrates.

As one example, in the process of forming the porous structure, the surface on which the porous structure is disposed may further be subjected to orienting treatment

In the liquid crystal optical device of the invention, in which the porous structure having the numerous through holes or blind holes is disposed between the substrates constituting the liquid crystal optical cell, the molecular array state of the liquid crystal can be controlled, so that the optical characteristics of the liquid crystal optical device can be changed.

Consequently, the liquid crystal optical device of the present invention can be provided with enhanced response speed, elevated uniformity of the structure disposed between the electrodes and improved reproducibility of structural formation, so that a convertible lens capable of electrically controlling the optical characteristics such as light refraction and a liquid crystal aberration compensation device for compensating aberration produced when recording or playing with an optical pickup can be put into practical use.

According to the method for producing the liquid crystal optical device of the invention, as the porous structure having the numerous through holes or blind holes is disposed on one of the substrates with the electrodes, the molecular orientation of the liquid crystal can readily be controlled to form the liquid crystal optical device capable of changing its optical characteristics.

In the process of forming the porous structure, the present invention makes it possible to form the alumina porous structure with holes made in a cylindrical or hexagonal column shape by subjecting a high-purity aluminum material to anodizing treatment

In the process of forming the porous structure, the present invention makes it possible to enhance fabricating efficiency for the porous structure by forming an alumina porous structure by subjecting the material of glass, resin, silicon, carbon or ceramic to etching treatment

Further, according to the present invention, the optical characteristics of the liquid crystal can easily be changed by subjecting the inner wall surface 12a of the porous structure thus formed to the orienting treatment to orient the liquid crystal in the numerous through holes or blind holes in a prescribed orientation direction.

According to the method for producing the liquid crystal optical device of the invention, since the porous structure having the numerous through holes or blind holes is formed by the steps of disposing the high-purity aluminum material on one or more substrates having electrodes or forming the high-purity aluminum film on the one or more substrates and subjecting the high-purity aluminum material or high-purity aluminum film to anodizing treatment, the fabricating processes including the anodizing treatment required for forming the porous structure can be simplified, thus to achieve reduction in production cost for the liquid crystal optical device.

The aforementioned and other objects and advantages of the invention will become more apparent from the following detailed description of particular embodiments of the invention taken in conjunction with the accompanying drawings.

### BRIEF DESCRIPTION OF THE DRAWINGS

The above mentioned and other features and objects of this invention and the manner of obtaining them will become more apparent and the invention itself will be better understood by reference to the following description of embodiments of the invention take in conjunction with the accompanying drawings wherein:

FIG. 1 is a schematic diagram showing the conventional liquid crystal optical device,

FIG. 2 is a diagram showing one example of high-speed responsivity of the liquid crystal optical device according to the invention,

FIG. 3 is a diagram showing the first embodiment of the liquid crystal optical device 100 (subjected to perpendicularly orienting treatment) according to the invention,

FIG. 4 is a cross sectional view taken along line A-A in FIG. 3,

FIG. 5(a) is a cross sectional view taken along line B-B in FIG. 3,

FIG. 5(b) is a cross sectional view taken along line C-C in FIG. 3,

FIG. 6 shows arrangement of electrodes and terminals of the substrate in the liquid crystal optical device 100 according to the invention,

FIG. 7 is a schematic diagram showing an electric circuit of the liquid crystal optical device 100 according to the invention,

FIG. 8 is a partially enlarged schematic diagram showing the liquid crystal optical device 100 according to the invention,

FIG. 9 is an explanatory diagram illustrative of the porous structure 12 in the crystal optical device 100 according to the invention,

FIG. 10 is a schematically perspective view of the porous structure 12 with holes, formed in a cylindrical column in the crystal optical device 100 according to the invention,

FIG. 11 is a schematically perspective view of the porous structure 12 with holes, formed in a hexagonal column in the crystal optical device 100 according to the invention,

FIG. 12(a) and (b) are photographs of the porous structure 12 formed by an anodizing method,

FIG. 13 shows the liquid-crystal molecular orientation of the crystal optical device 100 when supplied with an electric voltage,

FIGS. 14(a) and 14(b) are diagrams showing the second embodiment of the liquid crystal optical device 200 (subjected to horizontally orienting treatment) according to the invention,

FIG. 15 is a diagram showing the third embodiment of the liquid crystal optical device 300 (comprising the porous structure with blind holes) according to the invention,

FIG. 16 is a process chart showing the process of producing the porous structure 12 (by an anodizing method),

FIG. 17 is a process chart showing the process of producing the porous structure 12 (by an etching method),

FIG. 18 is a flow chart showing the first part of the first method for producing the liquid crystal optical device of the invention,

FIG. 19 is a flow chart showing the second part of the first method for producing the liquid crystal optical device of the invention, and

FIG. 20 is a flow chart showing the second method for producing the liquid crystal optical device of the invention.

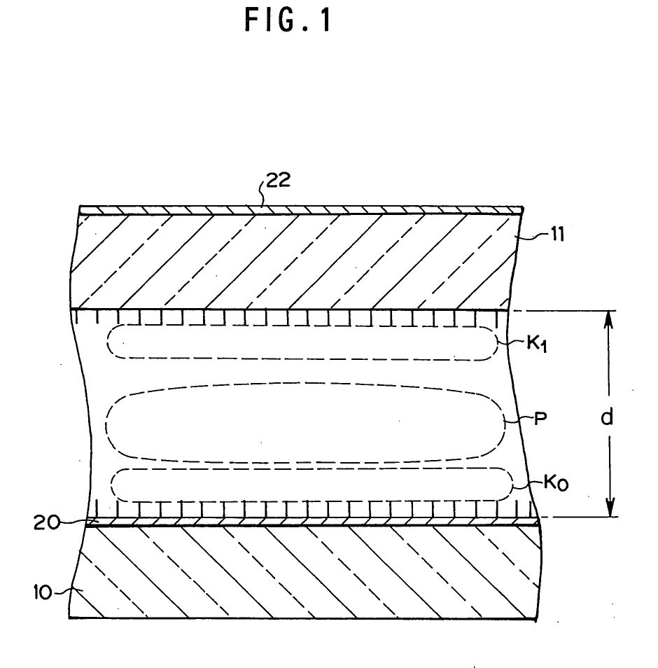

### DETAILED DESCRPTI ON OF THE PREFERRED EMBODIMENTS OF THE INVENTION

One of the preferred embodiments of a liquid crystal optical device and a method for producing the same according to the present invention will be described hereinafter with reference to the accompanying drawings. First, one example of the liquid crystal optical with a lens effect fulfilled by changing refractive-index distribution occurring in the liquid crystal optical cell with application of an electric field partly to the liquid crystal molecules oriented preliminary in a specific direction to change the orientation of the liquid crystal molecules will be explained.

At the setout, for a better understanding of the functional principle and effect of the liquid crystal optical device according to the present invention, the performance characteristics, specifically, responsivity and response dependency, of a common liquid crystal optical device of this kind will be explained here.

In the conventional liquid crystal device, the response time in a TN mode with respect to the responsiveness and response dependency of the liquid crystal optical device is expressed by the following formulae:

Rise time: τᵣ=4πηd²/(ε₀ΔεV²−4π³K)

Fall time: τ_{d}=ηd²/(Kπ²)

wherein, η: Viscosity of liquid crystal
d: Thickness of liquid crystal layer (between the oriented films)
ε₀: Dielectric constant of vacuum
Δε: Anisotropy of dielectric constant of liquid crystal
K: Elastic constant of liquid crystal
V: Applied voltage
T: Temperature characteristic (Property values of η, Δε and K are variable with temperature)

When applying an electric voltage to the liquid crystal optical device and then cutting off the electric voltage, the liquid crystal is reoriented The time required for reorienting the alignment of the liquid crystal is the response time τ. The response characteristic τᵣ (rise time) when applying the voltage and the response characteristic τ_{d} (fall time) when cutting off the voltage have a proportional relation with the viscosity η of the liquid crystal. The orientational relaxation to allow the alignment of the liquid crystal to return to its original orientation, which occurs when cutting off the voltage, is caused by an orientation restraining force of the oriented film, thus to take long time to restore a bulk portion away from the oriented film.

In general, it has been known that the response times τᵣ and τ_{d} are lengthened in proportion to the square of the layer thickness d (between the oriented films) of the liquid crystal. Therefore, decrease of the thickness d of the liquid crystal layer is effective for improvement in response characteristics. In the case of forming polymer network in the liquid crystal layer as performed in the aforementioned Non-Patent Literature 1 (mode of polymer dispersion-type liquid crystal), it has been known that the area per unit volume of an interface with the polymer is large, consequently to increase the response speed with respect to the orientational relaxation when cutting off the voltage. However, the polymer network tends to lack uniformity in the producing process.

The porous structure 12 of the liquid crystal device is provided with the numerous through holes or blind holes of nanosize to have a large surface a In this case, the liquid crystal in the nanosized holes is located whisker-close to the surface of the oriented film of the inner wall 12a of each hole. That is, the thickness d of the liquid crystal layer in the conventional liquid crystal optical device is equivalent to the aperture diameter of the hole in the porous structure 12 of the liquid crystal optical device of the invention.

It is apparent from the aforementioned formulae of the “rise time τᵣ” and “fall time τ_{d}” that the liquid crystal optical device of the invention using the porous structure 12 can ensure high-speed performance with respect to the responsivity of the liquid crystal. Thus, the great improvement in response speed of the liquid crystal optical device using the porous structure 12 could be verified.

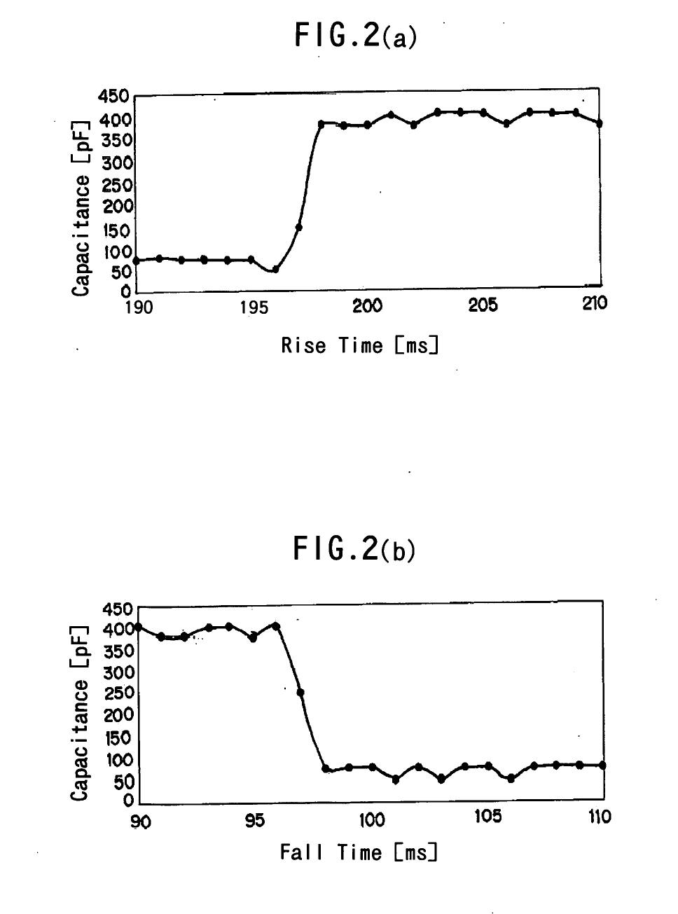

FIG. 2 shows one example of the high-speed responsivity of the liquid crystal optical device according to the present invention, wherein FIG. 2(a) is a diagram showing the relation between the rise time and electric capacitance, and FIG. 2(b) is a diagram showing the relation between the fall time and electric capacitance.

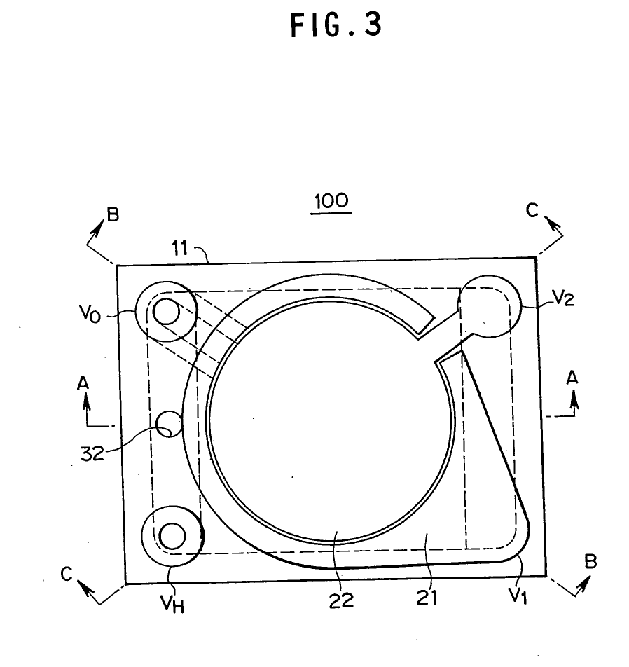

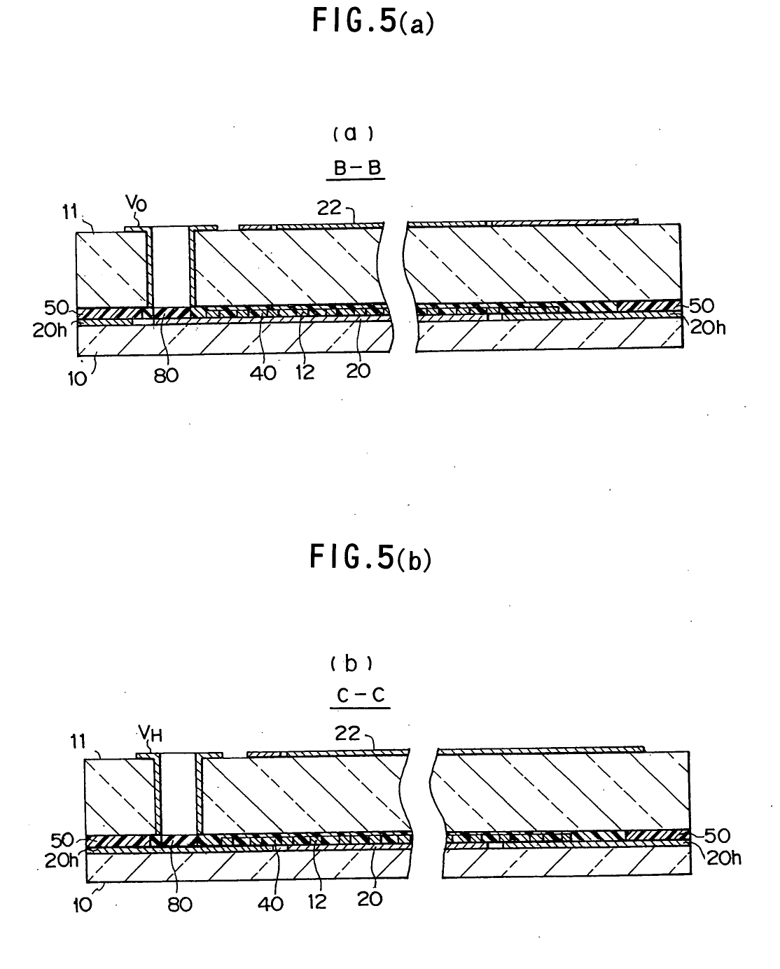

As illistrated in FIG. 3 through FIG. 6, the liquid crystal optical device 100 of the invention comprises a substrate 10 having a common electrode 20, a substrate 11 having a fist driving electrode 21 and a second driving electrode 22, a porous structure 12, and liquid crystal 40.

In this embodiment, the liquid crystal 40 is a nematic liquid crystal type having a positive anisotropic permittivity (Np liquid crystal) in which the longitudinal direction of the molecules is oriented in the direction of the electric field when applying the electric voltage thereto. On the inner wall surface 12a of each hole in the porous structure 12, a perpendicularly oriented film is formed.

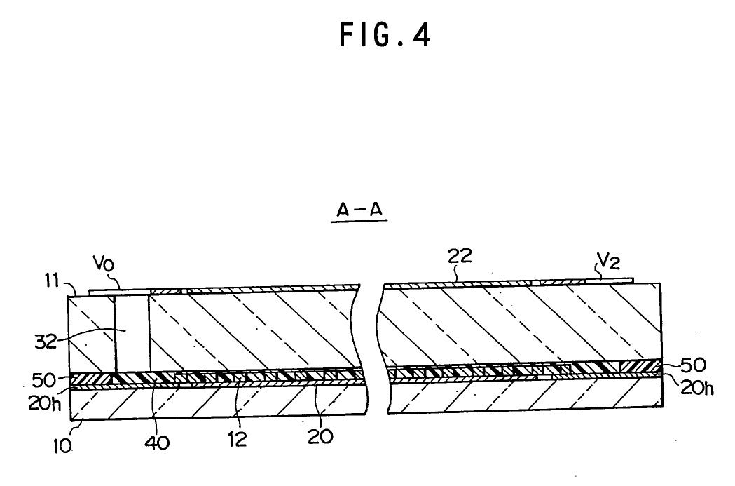

In FIG. 4, an oriented film and a transparent insulating layer, which are generally formed among the common electrode 20, first driving electrode 21, second driving electrode 22, the liquid crystal 40, and antireflection films disposed on the substrates 10 and 11 are omitted for ease of explanation. The liquid crystal 40 is sealed with a sealing material 50. To each of the terminals, lead wires or the like are connected for applying the electric voltage.

There are bored holes in the thickness direction of the upper glass substrate 11 for securing a ground terminal V0 and a heater terminal VH, which are connected to the common electrode 20 and heater electrode 20h, respectively. The upper glass substrate 11 is provided with a first driving terminal V1 and a second driving terminal V2. The common electrode 20 on the upper glass substrate 11 is connected to the ground terminal V0 on the upper glass substrate 11 through a conductor 80. Also, the heater electrode 20h is connected to the heater terminal VH on the upper glass substrate 11 through the conductor 80. Each terminal is formed by embedding metal plating conduction material such as Cr—Au into a through hole made in the inner peripheral surface of the hole.

The liquid crystal optical device is irrefrangible compared with the conventional liquid crystal optical cell because the electrodes are intensively arranged on the lateral side of the upper glass substrate 11 as illustrated in FIG. 3, so that it become harder to break, chip or fall into defective due to a lopsided force imposed on the cell. Therefore, the substrates 10 and 11 can be made thinner (e.g. 0.2 mm˜0.5 mm), thus to enable reduction in size and weight of the device.

A filler hole 32 for introducing the liquid crystal 40 into between the glass substrates 10 and 11 is formed in the upper glass substrate 11. The filler hole 32 is made in a cylindrical or elliptical column form and sealed with a sealant upon introducing the liquid crystal.

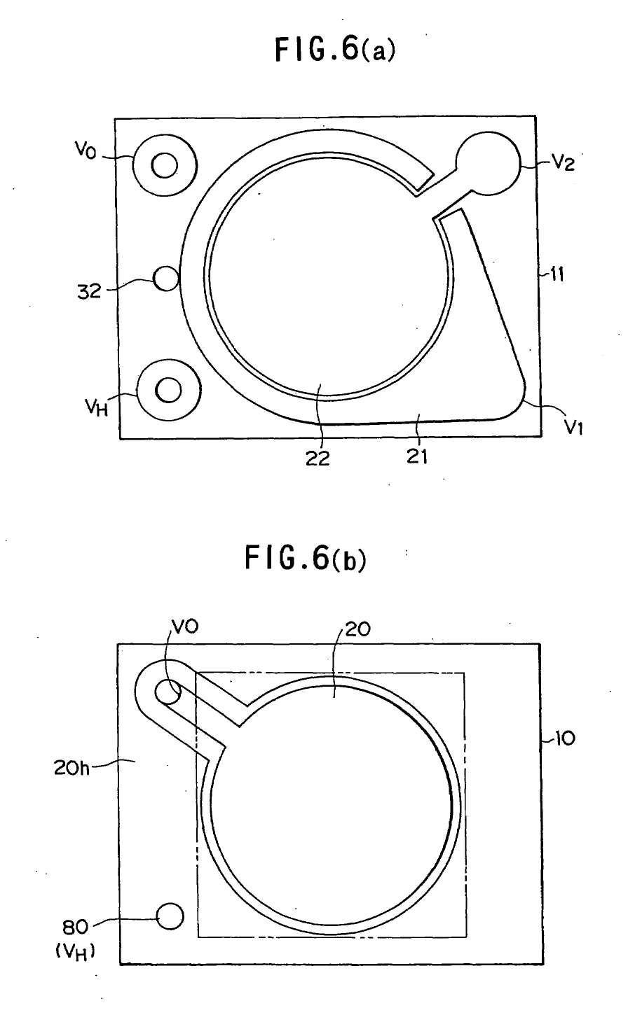

As shown in FIG. 6(a), the circular second driving electrode 22 is formed on the central portion of the upper glass substrate 11, and the first driving electrode 21 is formed around the second driving electrode. The second driving electrode 22 is connected to the second driving terminal V2. The first driving electrode 21 is connected to the first driving terminal V1. As shown in FIG. 6(b), the circular common electrode 20 is formed on the central portion of the substrate 10, and the heater electrode 20h is formed around the common electrode. The common electrode 20 is connected to the ground terminal V0, and the heater electrode 20h is connected to the heater terminal VH.

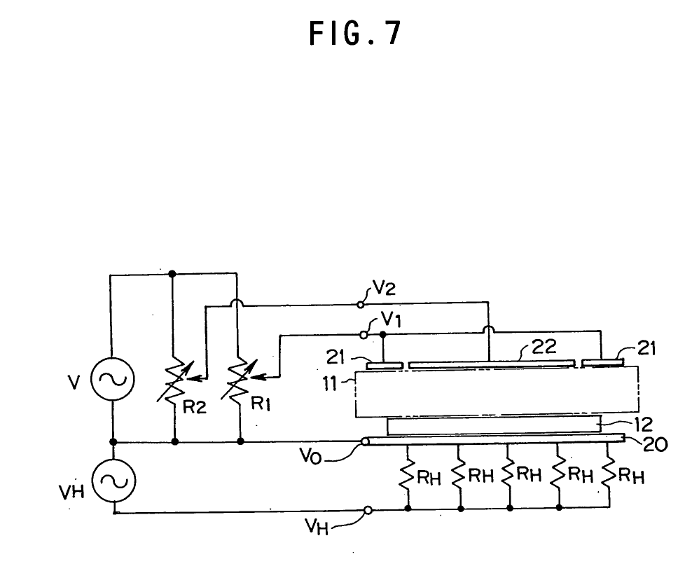

FIG. 7 shows schematically the electric circuit of the liquid crystal optical device 100 according to the invention. As shown in FIG. 7, a prescribed electric voltage V1 is supplied from an electric current source V to between the first driving terminal V1 and the ground terminal V0 through a variable resistance R1, and coincidentally, a prescribed electric voltage V2 is supplied to between the second driving terminal V2 and the ground terminal V0 through a variable resistance R1. A prescribed electric voltage VH is supplied from an electric current source VH to resistances RH through the ground terminal V0 and the heater terminal VH. The resistances RH serve as heaters of the liquid crystal optical device 100.

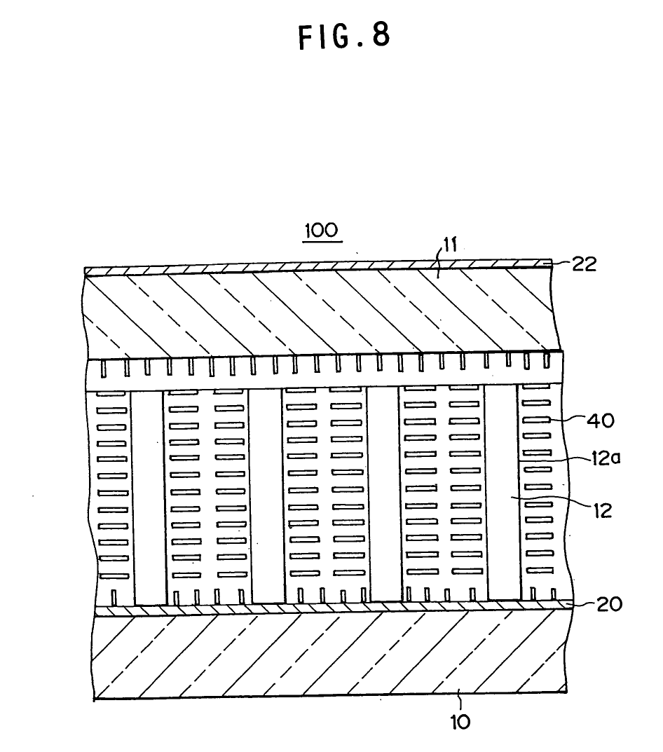

FIG. 8 schematically shows a part of the liquid crystal optical device 100 according to the invention. The part shown in FIG. 8 is an essential structure of the liquid crystal optical device 100. The porous structure 12 is disposed on the lower glass substrate 10. The upper glass subset 11 is disposed above the porous structure 12. Between the upper glass substrate 11 and the porous substrate 12, a prescribed space is formed. The liquid crystal 40 is filled into between the lower glass substrate 10 and the upper glass substrate 11.

On the inner surface of the glass substrate 10 or 11, the oriented film is formed. Thus, the liquid crystal on the inner surface of the glass substrate is oriented unidirectionally (vertical direction) as shown in FIG. 8. The inner wall surface 12a of the porous substrate 12 is subjected to orienting treatment to orient the liquid crystal in the direction perpendicular to the inner wall surface 12a. Hence, the liquid crystal of a nematic type having a positive anitropic permittivity (Np liquid crystal) is used in this case.

Between the inner surface of the glass substrate and the porous substrate 12, there is left a space with a distance of several μm for the purpose of absorbing production tolerance of the porous substrate 12 and fluctuation in spacing between the upper and lower glass substrates and introducing the liquid crystal thereinto. The liquid crystal held in the space has liquid crystal molecules parallel to the direction in which light advances and does not respond to an electric field impressed in the direction perpendicular to the upper and lower substrates.

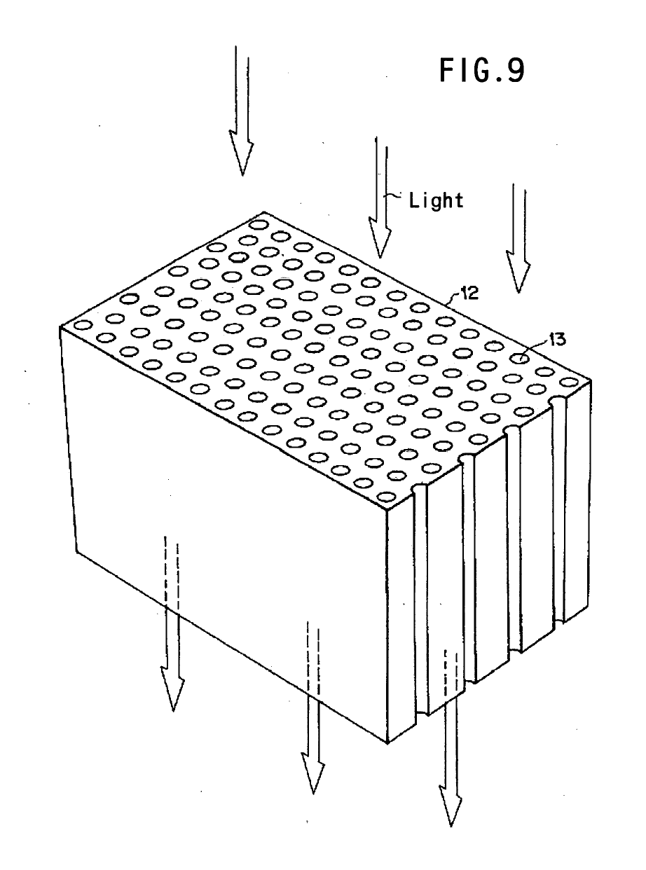

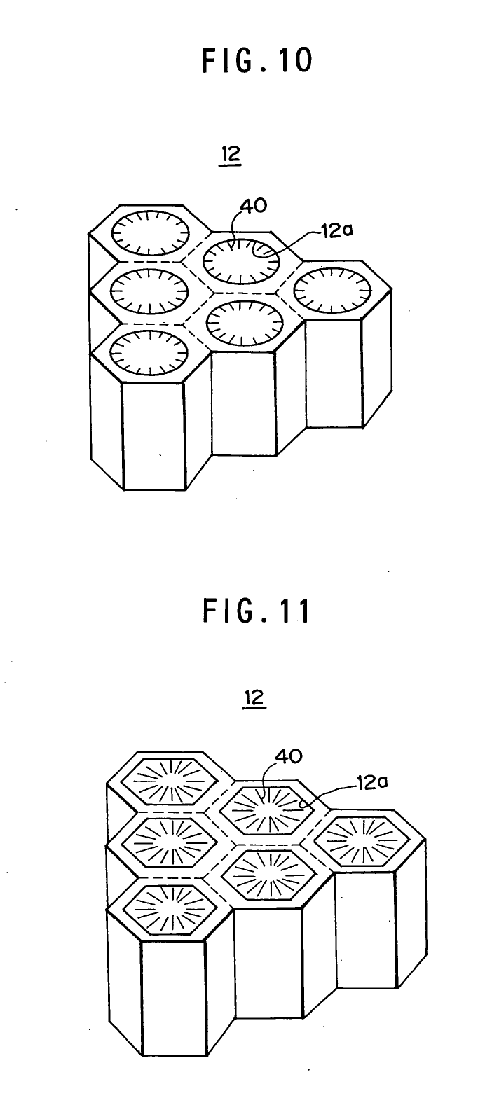

FIG. 9 is illustrative of the porous structure 12 in the crystal optical device. The through holes in the porous structure 12 each are formed in a cylindrical column structure as illustrated in FIG. 9. FIG. 10 schematically shows the porous structure 12 with holes, which is formed in a cylindrical column As shown in FIG. 10, the liquid crystal is oriented radially in the direction perpendicular to the inner wall surface 12a. FIG. 11 schematically shows the porous structure 12 with holes, which is formed in a hexagonal column. As shown in FIG. 11, the liquid crystal is oriented substantially radially in the direction perpendicular to the inner wall surface 12a.

The orientation of the liquid crystal subjected to perpendicularly orienting treatment on the inner wall surface 12a of the porous structure 12 assumes a pattern as shown in FIG. 10 or FIG. 11. To be specific, the in-plane orientation of the liquid crystal has no macroscopic anisotropy and is independent on polarization direction. The shape of the through hole, which is formed a cylindrical or hexagonal column structure, has functions of stoutening the structure, enlarging the aperture ratio s of the hole and filling the hole with the liquid crystal amply and plentifully.

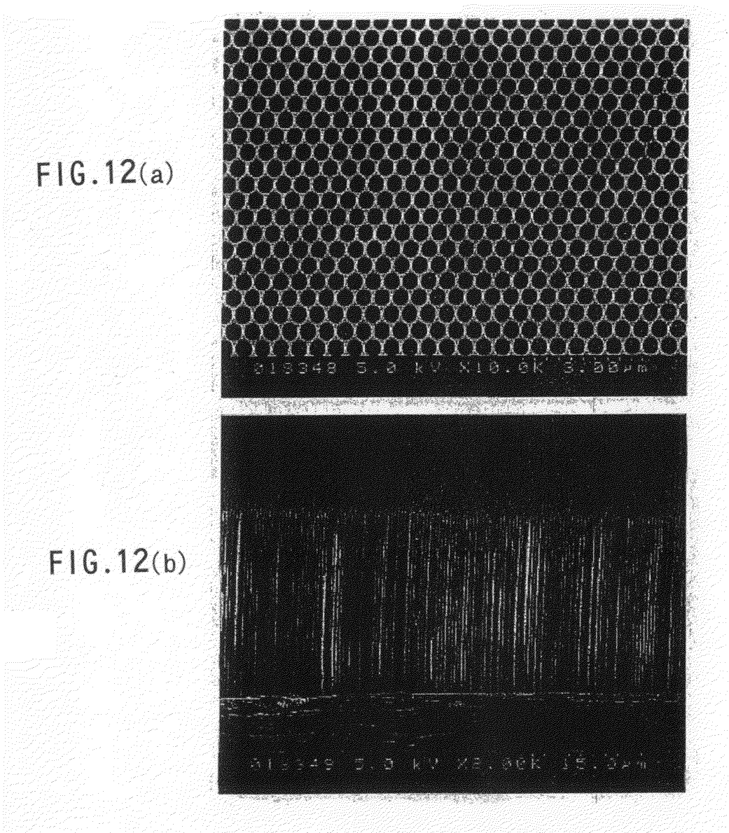

The porous structure 12 is formed by subjecting, for example, a high-purity aluminum material to anodizing treatment FIGS. 12(a) and 12(b) are photographs of the top and section of the porous structure 12 formed by an anodizing method. The through holes in the porous structure 12 are arranged at a pitch of about 500 nm and have an aperture diameter of about 400 nm and a thickness of about 50 μm.

The porous structure 12 contributes significantly to controlling of the optical characteristics of the liquid crystal with widening the surface area of the porous structure (area of the surface viewed in the light path direction normal to the substrate). Thus, it is desirable to widen the area of the liquid crystal. To be more specific, the through holes or blind holes filled with the liquid crystal can fulfill a wide effective area.

Further, it is desirable to use the porous structure 12 with high reliability and stability relative to light wavelength

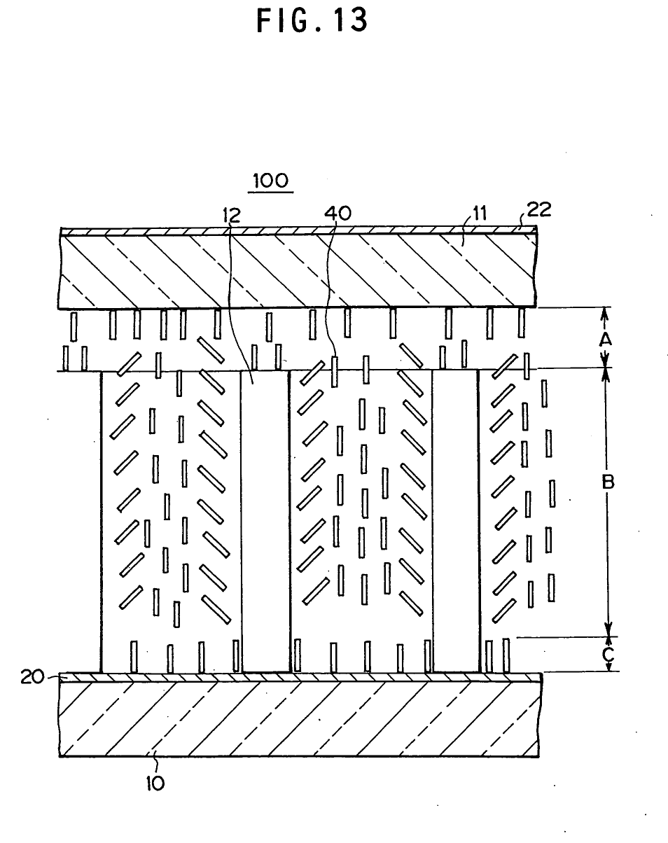

FIG. 13 shows the liquid-crystal molecular orientation of the crystal optical device 100 when supplied with an electric voltage. As shown in FIG. 13, the liquid crystal directed in the direction perpendicular to the inner wall surface 12a when applying the prescribed electric voltage to the liquid crystal device 100 changes the direction by the force acting in the direction of the electric field, and then, the liquid crystal is directed perpendicularly to the electrode when increasing the applied voltage. Thus, the refraction index of the liquid crystal relative to light can be controlled electrically, so that the liquid crystal device can efficiently be useful for an electronically varifocal lens and a liquid crystal aberration compensation device.

The orientation of the liquid crystal molecules in the regions “A” and “C” shown in FIG. 13 when applying the electric voltage to the liquid crystal does not change and remains its state oriented perpendicularly to the electrode. Thus, the characteristics of the liquid crystal molecules in the regions “A” and “C” are not influenced by the applied electric voltage. Meanwhile, the orientation of the liquid crystal molecules in the region “B” shown in FIG. 13 when applying the electric voltage to the liquid crystal changes with the applied electric voltage, so that the optical characteristics of the liquid crystal can be utilized as an optical element

As shown in the enlarged schematic diagram of the liquid crystal optical device 100 in FIG. 8, the through holes in the porous structure aligned parallel to the normal direction of the substrate and the direction in which light advances, and the liquid crystal molecules are oriented in the perpendicularly aligned state on the inner wall surface 12a subjected to perpendicularly orienting

The proportion in quantity of the liquid crystal filled and held within the blind holes in the porous substrate is increased with increasing the ape ratio s of the holes in the porous structure 12, e.g. narrowing the partition walls of the porous structure, consequently to militate for light controlling. The aperture ratio s is definable in the following equation:

Aperture ratio (s)=(area of holes)/{(area of holes)+(area of partition walls)}

In consideration of possible production tolerance of the porous substrate 12 and so forth, the aperture ratio s is preferably determined to about 50% to 80%.

Selection of the material for the partition walls of the porous structure is the most important matter in the light of the optical penetrating efficiency, particularly, antiweatherability to ultraviolet rays and temperature dependence of the partition walls. As an electric insulating material, there may be used glass, resin, silicon, carbon or ceramic, but any sort of material may be adequately selected as usage.

The liquid crystal material has birefringence of the order defined by a difference Δn(=nₑ−nₒ), wherein nₑ is the refraction index in the long axis direction of the liquid crystal molecules (referred to as an extraordinary index), and nₒ is the refraction index in the short axis direction of the same (referred to as an ordinary index). In the case of a nematic liquid crystal, the sign in the formula Δn(=nₑ−nₒ) is positive and signifies to categorize the liquid crystal to a positive crystal.

Here, the liquid crystal optical device with the aforementioned porous structure 12 will be numerically estimated using a nematic liquid crystal “ZLI-1132” made by Merck Ltd., Japan as an example in order to understand the optical function when irradiating light impinging perpendicularly onto the liquid crystal optical device. The extraordinary index (nₑ) of the liquid crystal material ZLI-1132 is about 1.632 and the ordinary index (nₒ) is about 1.493.

In the case where the orientation of the liquid crystal molecules in the through holes of the porous structure 12 when off-voltage is applied assumes a radial pattern as shown in FIG. 8, the maximum value n_{MAX} of an expected refraction index is a little smaller than the value nₑ, i.e. n_{MAX}=1.561, approximately. The minimum value n_{MIN} of the same when applying the electric voltage is equal to the value no, i.e. n_{MIN}=1.493. Thus, the controllable range (δn) of refraction index, which changes with the voltage, can be estimated to be δn=n_{MAX}−n_{MIN}=0.068, approximately.

The product of the refraction index and the geometric distance is referred to as an “optical distance”. In this instance, the maximum and minimum optical distance L become L_{MAX}=d·n_{MAX} and L_{MIN}=d·n_{MIN}, respectively, wherein d is the thickness of the liquid crystal layer (thickness of the porous structure). Therefore, the optical distance which can be controlled with the electric voltage is δL=d·δn.

The aforementioned estimation is satisfied when the aperture ratio s of the porous structure is 100%, but the controllable range (δ n) of the effectively variable refraction index is decreased with decreasing the aperture ratio s of the holes, depending on the applied voltage.

For instance, assuming that the porous structure made of alumina material formed by subjecting a high-purity aluminum material to anodizing treatment, which has an average refractive index of about 1.764 and an aperture ratio s of 50%, is used, the effective refiactive index when off-voltage is applied is defined by n_{MAX}=(1.561+1.764)×0.5=1.6625, and the effective refractive index when voltage is applied is defined by n_{MIN}=(1.493+1.764)×0.5=1.6285. Since the refraction index range (δn) controllable with application of electric voltage becomes one-half of the case (s=100%), the optical distance δL also becomes one-half of the case (s=100%).

The phase delay (phase-lag amount) Φ of the light passing through a light path having an optical distance L can be calculated by the following formula:

Phase-lag amount Φ=L×2π/λ

wherein L is the optical distance, and λ is a wavelength of light

Therefore, in the case where the aforementioned porous structure is made of alumina and has an aperture ratio s of 50%, the following formula is satisfied, wherein d is the thickness of the liquid crystal layer (thickness of the porous structure), and δ Φ is the phase delay (phase-lag amount) controllable with an electric voltage:

δΦ=(n_{MAX}−n_{MIN})×d×2π/λ=0.035×d×2π/λ

As is mentioned above, the liquid crystal optical device 100 in this embodiment comprises the substrate 10 having the common electrode 20, the substrate 11 having the first driving electrode 21 and the second driving electrode 22, the porous structure 12, and the liquid crystal 40. The method for producing the porous structure includes the process of subjecting the high-purity aluminum material to anodizing treatment to form the desired alumina porous structure. The numerous through holes 13 are made in the porous structure 12 in a cylindrical column shape. The inner wall surface 12a of the porous structure 12 is subjected to perpendicularly orienting treatment, and likewise, the surface on which the porous structure made of the upper and lower glass substrates (surface on which the porous structure 12 of the electrode 20 in the substrate 10) is subjected to perpendicularly orienting treatment

Therefore, the molecular orientation of the liquid crystal can be controlled by applying the electric voltage between the electrodes disposed on the glass substrates, thus to change the optical characteristics of the liquid crystal optical device. Hence, the response time of the liquid crystal optical device can be shortened, so that the liquid crystal optical device of the invention can be practically used as a liquid crystal aberration compensation device for compensating an aberration possibly caused in recording or playing by using an optical pickup.

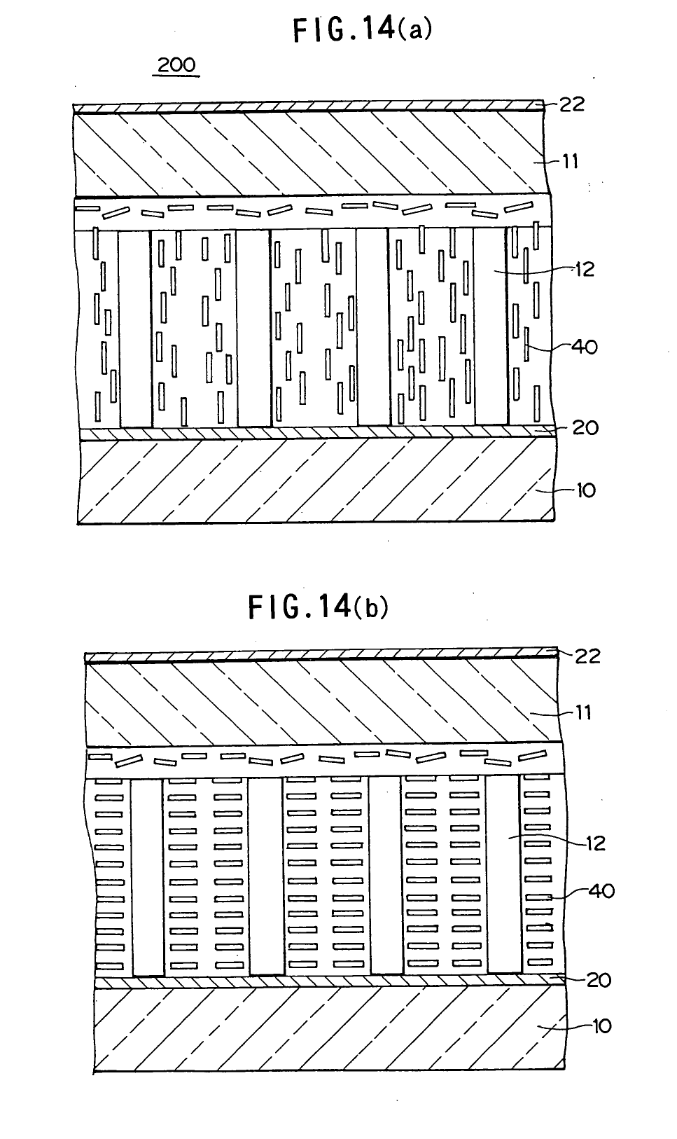

FIG. 14(a) shows the liquid-crystal molecular orientation of the crystal optical device 200 when off-voltage is applied, and FIG. 14(b) shows the liquid-crystal molecular orientation of the crystal optical device 200 when voltage is applied.

As illustrated in FIG. 14(a) and FIG. 14(b), the liquid crystal optical device 200 of the invention comprises a lower glass substrate 10 having a common electrode 20, a substrate 11 having a first driving electrode 21 and a second driving electrode 22, aporous structure 12, and liquid crystal 40.

In this embodiment, the liquid crystal 40 is a nematic liquid crystal type having a negative anisotropic permittivity (Nn liquid crystal) in which the longitudinal direction of the molecules is oriented in the direction perpendicular to the electric field when applying the electric voltage thereto. On the inner wall surface 12a of the porous structure 12, a horizontally oriented film having the long axis direction of the liquid crystal molecules directed in the depth direction is formed.

As shown in FIG. 14(a), the liquid crystal in the through holes of the porous structure 12 has the molecules oriented in the horizontal direction relative to the inner wall surface 12a In this instance, the liquid crystal molecules near the surfaces of the upper and lower substrates assume the random orientation.

In this instance, the liquid crystal within the through holes of the porous structure 12 is subjected to a force perpendicular to the electric field when applying the electric voltage between the electrodes. Thus, the liquid crystal molecules change to its orientation in the direction perpendicular to the inner wall surface 12a, but the liquid crystal molecules near the upper and lower glass substrates remain their randomly oriented state.

The liquid crystal optical device 200 in this embodiment has the same effect as that brought about by the first embodiment as described above.

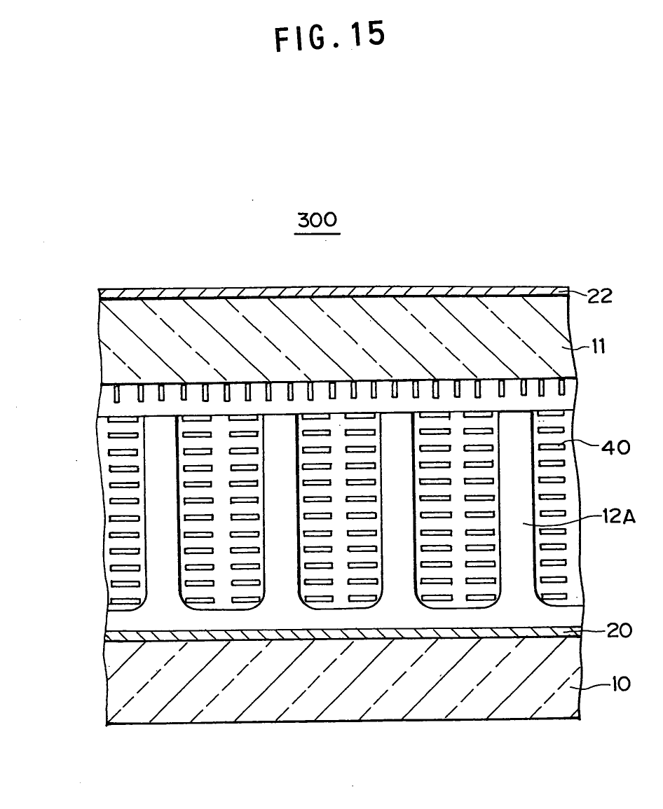

FIG. 15 schematically shows the liquid crystal optical device 300 in the third embodiment of the invention. As shown in FIG. 15, the liquid crystal optical device 300 comprises a glass substrate 10 having a common electrode 20, a glass substrate 11 having a first driving electrode 21 and a second driving electrode 22, a porous structure 12A, and liquid crystal 40.

In this embodiment, the porous structure 12A has numerous blind holes. The liquid crystal 40 is a nematic liquid crystal type having a positive anisotropic permittivity (Np liquid crystal) in which the longitudinal direction of the molecules is oriented in the direction of the electric field when applying the electric voltage thereto. On the inner wall surfaces 12a of each blind hole in the porous structure 12, a perpendicularly oriented film is formed.

Before applying an electric voltage, the liquid crystal within each blind hole of the porous structure 12A is radially oriented perpendicularly to the inner wall surfaces 12a, and the liquid crystal on the surface of the glass substrate, which is subjected to orienting treatment, is oriented perpendicularly to the surface of the glass substrate. When applying the electric voltage, the liquid crystal in each blind hole of the porous structure 12A changes from the perpendicularly oriented state to the horizontally oriented state relative to the inner wall surface 12a of the hole, but the liquid crystal on the treated glass substrate remains the perpendicularly oriented state.

The liquid crystal optical device 300 in this embodiment has the same effect as that brought about by the first embodiment as described above. In the case of subjecting the high-purity aluminum material to anodizing treatment, a process of treating remaining portions of aluminum material, which are other than those subjected to the anodizing treatment or back-etching treatment for removing closed parts in the blind holes can be simplified (cf FIG. 14 described later).

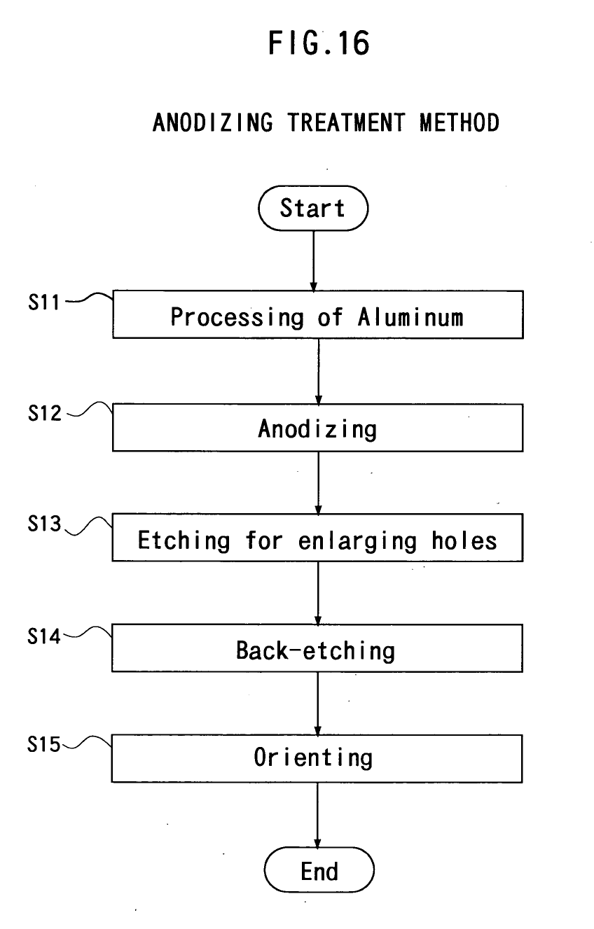

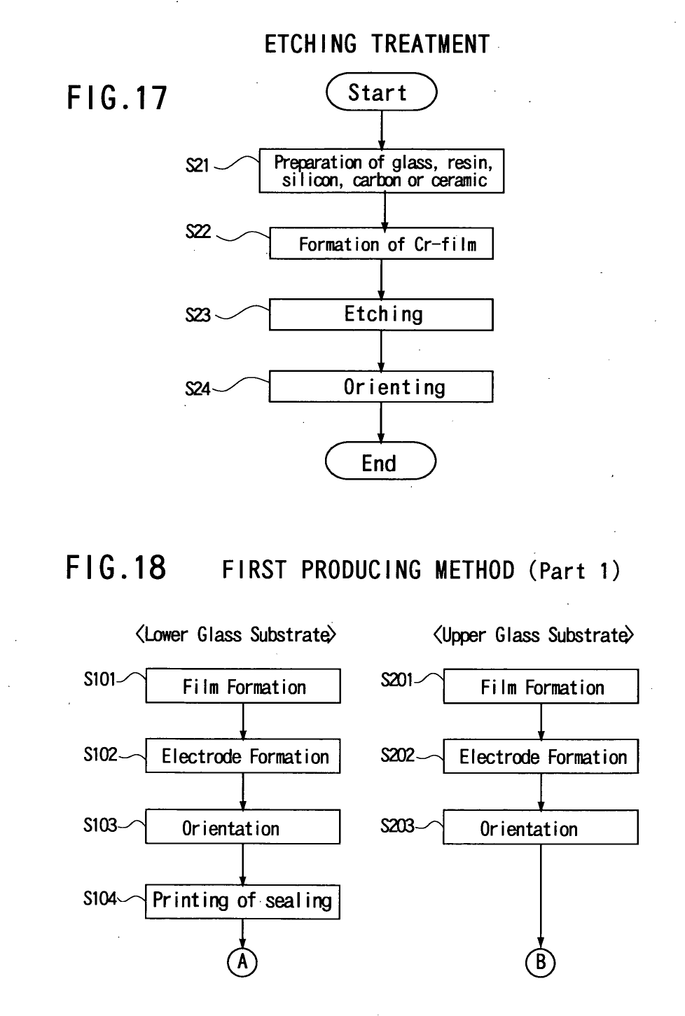

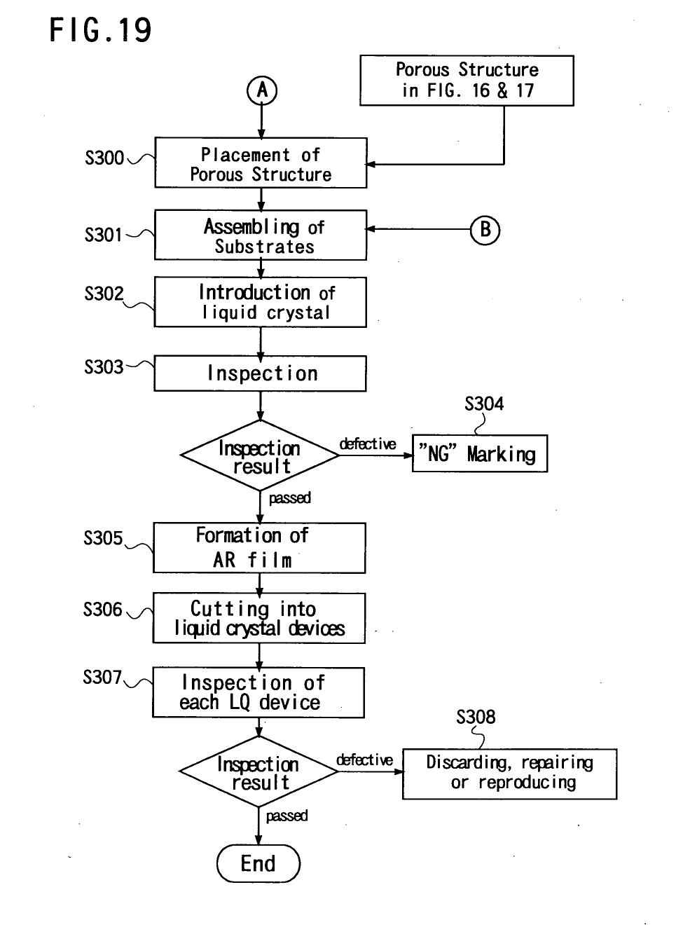

The method for producing the liquid crystal optical device 100 in the first embodiment of the invention will be described hereinafter with reference to FIG. 16 through FIG. 19. FIG. 16 is a process chart showing the process of producing the porous structure 12 (by an anodizing method), FIG. 17 is a process chart showing the process of producing the porous structure 12 (by an etching method), FIG. 18 is a flow chart showing the first part of the first method for producing the liquid crystal optical device, and FIG. 19 is a flow chart showing the second part of the first method for producing the liquid crystal optical device.

To be more specific, the producing method for the porous structure 12 as shown in FIG. 16 employs the treatment for anodizing high-purity aluminum.

As shown in FIG. 16, this method comprises shaping a high-purity aluminum material into a plate form having a prescribed thickness (S11), and then, subjecting the high-purity aluminum material to the anodizing treatment (S12). The anodizing treatment is effected by connecting the high-purity aluminum material to one of anodizing electrodes in acidic electrolyte such as of nitric acid and phosphoric acid, placing the other anodizing electrode in the acidic electrolyte, and applying an electric voltage between the anodizing electrodes. In such a manner, the desired porous structure having the numerous through holes or blind holes can be obtained.

Then, the porous structure 12 thus treated is subjected to etching treatment to provide the holes in the-porous structure 12 with a predetermined aperture diameter (S13).

Next, the porous structure 12 thus etched is subjected to back-etching treatment to remove remaining portions of aluminum material, which are other than those subjected to the anodizing treatment or closed parts in the blind holes (S14).

Thereafter, an oriented film is formed on the inner wall surface 12a of each through hole in the porous structure by using liquid crystal alignment materials including, for instance, a surface acting agent such as CTAB, water repellent agent, and polyimide, PVA (S15).

Next, the method for producing the porous structure 12 as shown in FIG. 17 is performed by etching glass, resin, silicon, carbon or ceramic to be made in a plate form having a prescribed thickness (S21), and then, forming a Cr-film or resist film on the plate-formed glass, resin, silicon, carbon or ceramic (S22). After exposing the resist film, etching treatment is performed to make each through hole in the porous structure 12, which has a prescribed aperture diameter (S23). The through hole is made to have the aperture diameter of about 5000 nm by way of example. Then, an oriented film is formed on the inner wall surface 12a of the through hole (S24), consequently to complete the porous structure 12 having the cylindrical holes as shown in FIG. 10.

As a primary process for producing the liquid crystal optical device 100, an electrode material is formed on the lower glass substrate (substrate 10) by an evaporation method or the like as shown in FIG. 18 (S101). A patterning method such as etching is performed to form the electrodes 20 and 21 (S102). Meanwhile, the order of the process of forming the terminals as mentioned earlier and the process of forming the electrodes may be changed.

After laminating a transparent insulating layer if needed, a liquid crystal oriented film such as of PVA is formed (S103), and then, a seating material 50 is formed on the outer side of the electrode 20 by printing or the like for occluding the liquid crystal (S104).

On the other hand, the opposite upper glass substrate (substrate 11) as a parent substrate is provided with the electrode (S201) and subjected to patterning to form the first driving electrode 21 and second driving electrode 22 (S202). Further, the liquid crystal oriented film is formed (S203).

Then, as illustrated in FIG. 19, porous structure is disposed (S300). That is, the porous structure 12 formed by one of two methods shown in FIG. 16 and FIG. 17 is disposed Next the upper glass substrate and the lower glass substrate are assembled in opposition to each other and united with a sealing material through a spacer (S301).

Subsequently, the liquid crystal is introduced into the inside of the sealing material through a filler hole 32 and then sealed (S302). Next an operation inspection for the device is performed using the terminals arrayed on the upper glass substrate 11 as a parent substrate (S303). If a defect is detected in the device as the result of the operation inspection, the liquid crystal optical device with the defect is marked “NG” (S304). The device that has to pass the operation inspection is processed to form antireflective film (AR film) on the whole surface of the parent substrate (S305). The AR film may be formed on one or both of the glass substrate 10 and the substrate 11.

Last, the parent substrate is cut into pieces of the liquid crystal aberration compensation device 1 by using a slicer or the like (S306), and then, the inspection process for individual device is finished (S307). The device judged to be “defective” as the result of the inspection may be discarded, repaired or reproduced (S308).

In the producing method described above, the porous structure 12 is preliminary formed and disposed between the upper and lower glass substrates when assembling.

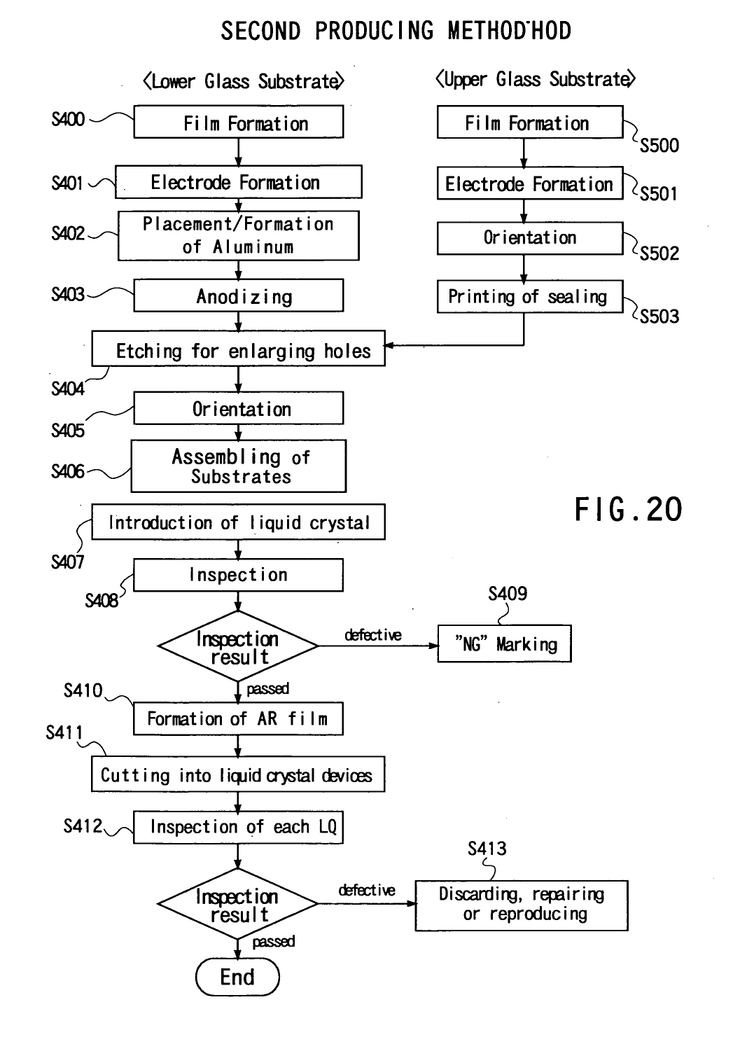

In the second producing method for the liquid crystal optical device 100 as shown in FIG. 20, in the assembling of the liquid crystal optical device 100, the anodizing treatment is effected for the high-purity aluminum material to form the porous structure 12. FIG. 20 shows the second method for producing the liquid crystal optical device of the invention.

In this second producing method, the electrodes are formed at prescribed portions on the lower glass substrate (substrate 10) by an evaporation method or the like in Step S400 after film formation on the lower glass substrate and patterning treatment Then, the electrodes 20 and 21 are formed by a patterning method such as etching (S401).

Subsequently, in Step S402, a high-purity aluminum material is disposed or a high-purity aluminum film is formed. Then, the high-purity aluminum material is subjected to anodizing treatment (S403). The anodizing treatment in this step is the same at that mentioned above. Consequently, the porous structure with numerous through holes is obtained.

Next the porous structure 12 thus obtained is subjected to etching treatment to make the holes larger (S404). As one example, the through hole is treated so as to have a diameter of about 80 nm.

Last, an oriented film is formed on the inner wall surface 12a of each through hole (S405). Consequently, the porous structure 12 with numerous cylindrical through holes as shown in FIG. 9 can be obtained.

On the other hand, electrodes are formed on the upper glass substrate (substrate 11) in the same way as above (S500), to form the first driving electrode 21 and the second driving electrode 22 by patterning (S501). Likewise, the liquid crystal oriented film is formed (S502), and then, a sealing material 50 is formed on the outer side of the electrode 20 by printing or the like for occluding the liquid crystal (S503).

Next the substrate having the electrodes and terminals and the upper glass substrate are assembled in opposition to each other and united with a sealing material through a spacer (S406).

Subsequently, the liquid crystal is introduced into the inside of the sealing material through a filler hole 32 and then sealed (S407). Next an operation inspection for the device is performed using the terminals arrayed on the parent substrate 10 (S408). If a defect is detected in the device as the result of the operation inspection, the liquid crystal optical device with the defect is marked “NG” (S409). The device that has to pass the operation inspection is processed to form antireflective film (AR film) on the whole surface of the parent substrate (S410). The AR film may be formed on one or both of the substrate 10 and the substrate 11.

Last, the parent substrate is cut into pieces of the liquid crystal aberration compensation device 1 by using a slicer or the like (S411), and then, the inspection process for individual device is finished (S412). The device judged to be “defective” as the result of the inspection may be chucked out, repaired or sent to a reproducing process (S413).

According to the aforementioned producing method for the liquid crystal optical device, the molecular orientation of the liquid crystal can readily be controlled to form the liquid crystal optical device capable of changing its optical characteristics.

In the process of forming the porous structure, an alumina porous structure may be formed by subjecting a high-purity aluminum material to anodizing treatment

In the process of forming the porous structure, the present invention makes it possible to enhance fabricating efficiency for the porous structure by forming an alumina porous structure by subjecting the material of glass, resin, silicon, carbon or ceramic to etching treatment

Although the embodiments in which the porous structure 12 is formed by subjecting the high-purity aluminum material to the anodizing treatment has been described above, this invention should not be understood as being limited to the aforementioned embodiments. For instance, Si (silicon) material may be used and subjected to the etching treatment to form the porous structure.

Further, although the shape of each through hole in the porous structure is formed in a cylindrical or hexagonal column shape, this shape is by no means limited thereto and the through hole may have any other desired shape.

The upper surface or lower surface of the porous structure may be subjected to blacking treatment to reduce light leakage.

As is apparent from the foregoing description, this invention can provide the liquid crystal optical device having an autofocusing function and a micro-macro switching function extensively applicable to a subminiature camera built into a cell phone, personal digital assistance (PDA), digital equipment and so on, and available as a liquid crystal aberration compensation device for compensating aberration produced in recording and playing with an optical pickup in an optical disk device.

While the invention has been explained by reference to particular embodiments thereof, and while these embodiments have been described in considerable detail, the invention is not limited to the representative apparatus and methods described. Those of ordinary skill in the art will recognize various modifications which may be made to the embodiments described herein without departing from the scope of the invention. Accordingly, the scope of the invention is to be determined by the following claims.

What is claimed is:

1. A liquid crystal optical device comprising a plurality of substrates having electrodes, a porous structure having numerous through holes or blind holes and disposed between said substrates, and liquid crystal held between said substrates to be filled in said through holes or blind holes.

2. The liquid crystal optical device set forth in claim 1, wherein said through holes or blind holes each are formed in a cylindrical or hexagonal column structure.

3. The liquid crystal optical device set forth in claim 1, wherein said porous structure has an aperture ratio of 50% to 80%.

4. The liquid crystal optical device set forth in claim 2, wherein said porous structure has an aperture ratio of 50% to 80%.

5. The liquid crystal optical device set forth in claim 1, wherein said through holes or blind holes are arranged at a pitch of 50 to 5000 nm.

6. The liquid crystal optical device set forth in claim 2, wherein said through holes or blind holes are arranged at a pitch of 50 to 5000 nm.

7. The liquid crystal optical device set forth in claim 1, wherein said liquid crystal has in-plane orientation having no anisotropy and being independent on polarization direction, and said porous structure having an inner wall surface subjected to orienting treatment and an surface of said substrate, on which the porous structure is formed, subjected to orienting treatment.

8. The liquid crystal optical device set forth in claim 2, wherein said liquid crystal has in-plane orientation having no anisotropy and being independent on polarization direction, and said porous structure having an inner wall surface subjected to orienting treatment and an surface of said substrate, on which the porous structure is formed, subjected to orienting treatment.

9. The liquid crystal optical device set forth in claim 1, wherein said porous structure has an upper surface and a lower surface, one of said upper surface and lower surface being subjected to blacking treatment to reduce light leakage.

10. The liquid crystal optical device set forth in claim 2, wherein said porous structure has an upper surface and a lower surface, one of said upper surface and lower surface being subjected to blacking treatment to reduce light leakage.

11. A method for producing a liquid crystal optical device with a plurality of substrates having electrodes and liquid crystal held between said substrates, said method comprising the processes of forming said electrodes on said substrates, forming a porous structure having an inner wall surface and numerous through holes or blind holes, subjecting said inner wall surface of said porous structure to orienting treatment, disposing said porous structure on one of said substrates with said electrodes, assembling the other substrate with said substrate on which said porous structure is disposed, and introducing said liquid crystal into between the assembled substrates.

12. The method for producing a liquid crystal optical device set forth in claim 11, wherein said process for forming the porous structure includes subjecting a high-purity aluminum material to anodizing treatment to form an alumina porous structure.

13. The method for producing a liquid crystal optical device set forth in claim 11, wherein said process for forming the porous structure includes subjecting a material of glass, resin, silicon, carbon or ceramic to etching treatment to form the porous structure.

14. The method for producing a liquid crystal optical device set forth in claim 11, further comprising a process of subjecting a surface onto which said porous structure is attached to the orienting treatment.

15. The method for producing a liquid crystal optical device set forth in claim 12, further comprising a process of subjecting a surface onto which said porous structure is attached to the orienting treatment.

16. The method for producing a liquid crystal optical device set forth in claim 13, further comprising a process of subjecting a surface onto which said porous structure is attached to the orienting treatment.

17. A method for producing a liquid crystal optical device with a plurality of substrates having electrodes and liquid crystal held between the aforesaid substrates, said method comprising the processes of forming said electrodes on said substrates, disposing a high-purity aluminum material on one or more substrates having electrodes or forming a high-purity aluminum film on said one or more substrates, subjecting said high-purity aluminum material or high-purity aluminum film to anodizing treatment to form a porous structure having an inner wall surface and numerous trough holes or blind holes, subjecting the inner wall surface of said porous structure to orienting treatment, assembling the other substrate with said substrate on which said porous structure is disposed, and introducing said liquid crystal into between the assembled substrates.

18. The method for producing a liquid crystal optical device set forth in claim 17, further comprising a process of subjecting a surface onto which said porous structure is attached to the orienting treatment.
